(19) United States
(12) Patent Application Publication
(10) Pub. No.: US 2026/0305372 A1
(43) Pub. Date: Oct. 1, 2026

(54) SEMICONDUCTOR PACKAGE AND METHOD OF MANUFACTURING THE SAME

(71) Applicant: Taiwan Semiconductor Manufacturing Company, Ltd., Hsinchu (TW)

(72) Inventors: Kuan-Lin Ho, Hsinchu City (TW); Chi-Yang Yu, Taoyuan City (TW); Jung-Wei Cheng, Hsinchu City (TW); Tsung-Ding Wang, Tainan (TW)

(73) Assignee: Taiwan Semiconductor Manufacturing Company, Ltd., Hsinchu (TW)

(21) Appl. No.: 19/093,285

(22) Filed: Mar. 28, 2025

(51) Int. Cl. H01L 21/48

(52) U.S. Cl. CPC H10W 70/05; H10W 70/093; H10W 70/095

(57) ABSTRACT

A manufacturing method of a semiconductor package is provided. The manufacturing method includes the following steps. A circuit substrate is provided, wherein the circuit substrate comprises a first build-up layer on a first side of the circuit substrate, and a second build-up layer on a second side of the circuit substrate opposite to the first side. A first mask layer with openings is formed on the second build-up layer. A redistribution structure is formed over the second side while leaving the first side free of any redistribution structure, wherein forming the redistribution structure comprises forming first conductive vias through the openings of the first mask layer to be electrically connected with the second build-up layer. First conductive terminals are formed on the redistribution structure away from the first conductive vias. A singulation process is performed to cut through the redistribution structure, the mask layer and the circuit substrate to form a substrate structure.

### BACKGROUND

Contemporary high performance computing systems consisting of one or more electronic devices have become widely used in a variety of advanced electronic applications. When integrated circuit components or semiconductor chips are packaged for these applications, one or more chip packages are generally bonded to a circuit carrier (e.g., a system board, a printed circuit board, or the like) for electrical connections to other external devices or electronic components. To respond to the increasing demand for miniaturization, higher speed and better electrical performance, more creative packaging and assembling techniques are actively researched.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1D are schematic cross-sectional views of various stages of manufacturing a substrate structure in accordance with some embodiments.

FIG. 2 to FIG. 4 are schematic cross-sectional views of variations of a substrate structure in accordance with some embodiments.

FIG. 5 is a schematic cross-sectional view of an application of a substrate structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

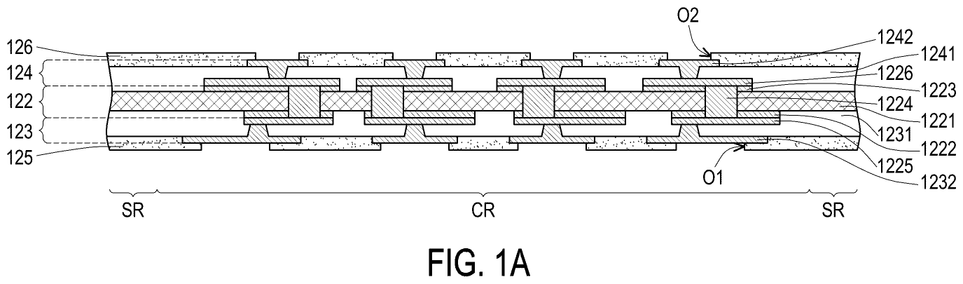

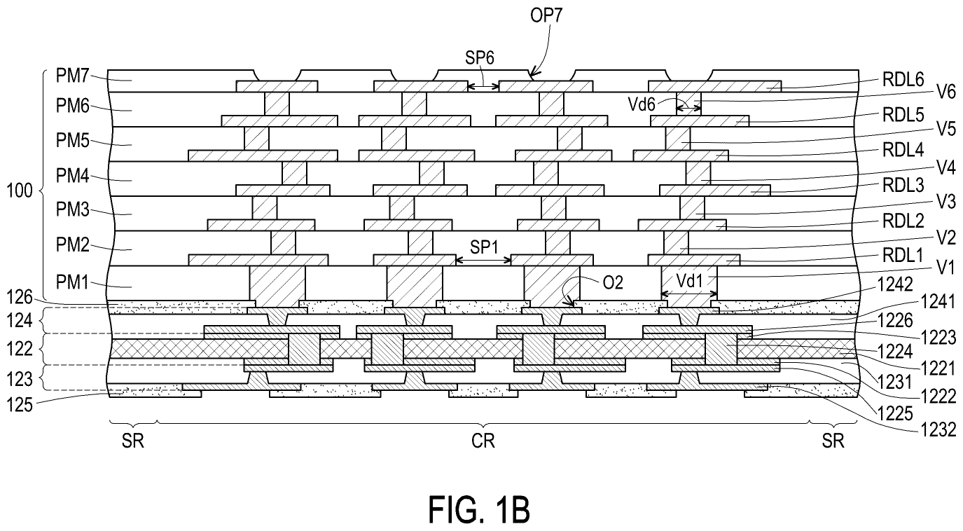

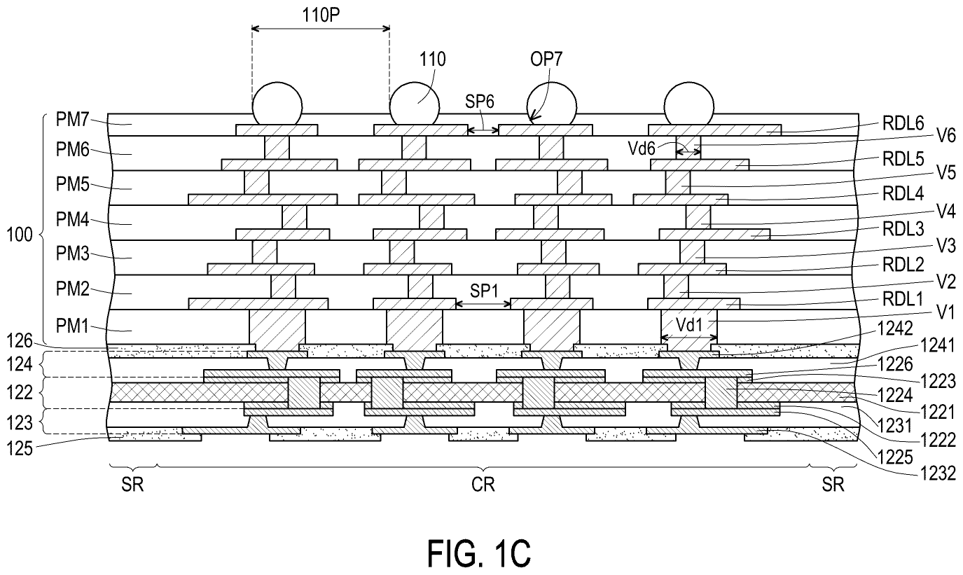

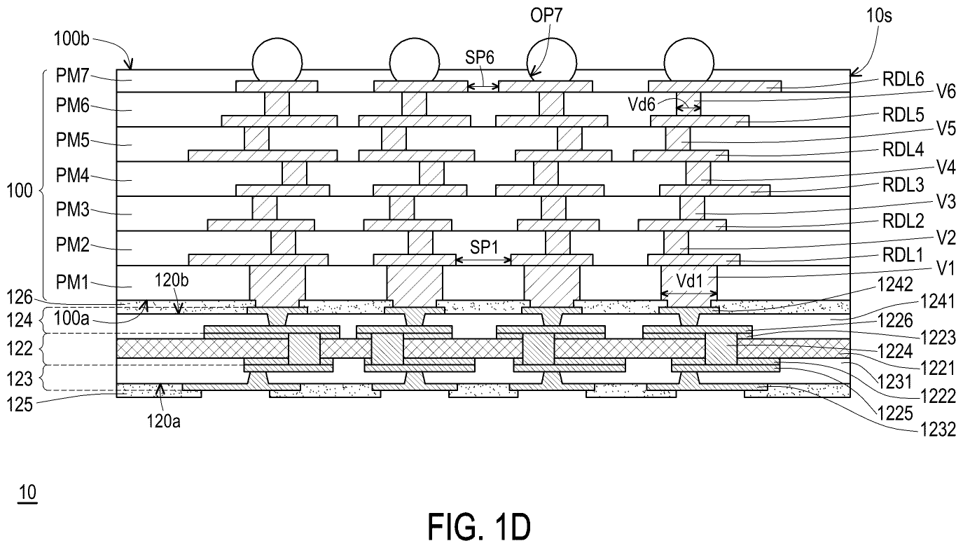

FIG. 1A to FIG. 1D are schematic cross-sectional views of various stages of manufacturing a substrate structure in accordance with some embodiments.

Referring to FIG. 1A, a circuit substrate 120 is provided. The circuit substrate 120 is provided in a panel format. For example, in a top-down view, the circuit substrate 120 has a rectangular shape. In some embodiments, the circuit substrate 120 is or includes a commercial printed circuit board (PCB). In some embodiments, the circuit substrate 120 is formed with a plurality of circuit regions CR. For ease of explanation, FIG. 1A only shows one circuit region CR. However, any person having ordinary skill in the art should understand that, the circuit substrate 120 in the panel form generally includes a plurality of circuit region CR arranged in an array, in a top-down view. Further, in some embodiments, the neighboring circuit regions CR are separated by a scribe line region SR. During the subsequent singulation process, scribe lines may be located in the scribe line region SR. Each of the circuit regions CR may be similarly sized and shaped, although in other embodiments the circuit regions CR may have different sizes and shapes.

In some embodiments, as shown in FIG. 1A, the circuit substrate 120 includes a core layer 122, a first build-up layer 123 and a second build-up layer 124 disposed on two opposing sides of the core layer 122. In some embodiments, the core layer 122 includes a core dielectric layer 1221, a first core conductive layer 1222 and a second core conductive layer 1223 disposed on two opposing sides of the core dielectric layer 1221, and a first conductive lid 1225 and a second conductive lid 1226 located respectively on the first core conductive layer 1222 and the second core conductive layer 1223. The core dielectric layer 1221 may be or may include prepreg (which contains epoxy, resin, silica filler and/or glass fiber), Ajinomoto Buildup Film (ABF), resin coated copper foil (RCC), polyimide, photo image dielectric (PID), ceramic core, glass core, molding compound, a combination thereof, or the like. However, the disclosure is not limited thereto, and other dielectric materials may also be used. The materials of the first core conductive layer 1222 and the second core conductive layer 1223 may include copper, gold, tungsten, aluminum, silver, gold, a combination thereof, or the like. In some embodiments, the first core conductive layer 1222 and the second core conductive layer 1223 are copper foils coated or plated on the opposite sides of the core dielectric layer 1221. In some embodiments, the first conductive lid 1225 and the second conductive lid 1226 include copper or other suitable conductive material.

In some embodiments, a plurality of conductive through holes 1224 penetrating through the core layer 122 provide electrical paths between the electrical circuits located on the opposite sides of the core layer 122. The first build-up layer 123 may be physically and electrically connected to the second build-up layer 124 through the conductive through holes 1224. In some embodiments, the conductive through holes 1224 are lined with a conductive material and filled up with an insulating material. In some embodiments, the method of forming the conductive through holes 1224 includes the following operations. First, through holes (not shown) are formed in the core dielectric layer 1221 at the predetermined positions by, for example, a mechanical or laser drilling, an etching, or another suitable removal technique. A desmear treatment may be performed to remove residues remaining in the through holes. Subsequently, the sidewall of the through holes may be plated with one or more conductive materials to a predetermined thickness, thereby providing the conductive through holes 1224. For example, the through holes may be plated with copper or other conductive material with an electroplating or an electroless plating.

In some embodiments, as shown in FIG. 1A, the first build-up layer 123 is formed over the core conductive layer 1222 of the core layer 122, and the second build-up layer 124 is formed over the core conductive layer 1223 of the core layer 122. In some embodiments, the first build-up layer 123 includes a plurality of first dielectric layers 1231 and a plurality of first conductive patterns 1232 alternately stacked over the first side of the core layer 122, and the second build-up layer 124 includes a plurality of second dielectric layers 1241 and a plurality of second conductive patterns 1242 alternately stacked over the second side of the core layer 122. The via portions of the first conductive patterns 1232 and the via portions of the second conductive patterns 1242 may be tapered toward the core layer 122. Although only one layer of conductive patterns and one layer of dielectric layers are illustrated for each of the first build-up layer 123 and the second build-up layer 124, the scope of the disclosure is not limited thereto. The materials of the first and second dielectric layers 1231 and 1241 may be or may include ABF, prepreg, RCC, polyimide, PID, polybenzooxazole (PBO), benzocyclobutene (BCB), silicon nitride, silicon oxide, phosphosilicate glass (PSG), borosilicate glass (BSG), boron-doped phosphosilicate glass (BPSG), molding compound, a combination thereof, or the like. The first and second dielectric layers 1231 and 1241 may be formed by a lamination process, a coating process, or the like. In some embodiments, the materials of the first and second conductive patterns 1232 and 1242 may be or may include metal, such as aluminum, titanium, copper, nickel, tungsten, and/or alloys thereof. The first and second conductive patterns 1232 and 1242 may include metal lines and vias. In some embodiments, a thickness of each of the first and second dielectric layers 1231 and 1241 is in a range of 10 μm to 20 μm, and a thickness of each of the first and second conductive patterns 1232 and 1242 is in a range of 10μm to 20 μm.

In some embodiments, the total number of layers of the first build-up layer 123 may sum up to a total of 0 to 8 layers for the conductive patterns and dielectric layers, and the total number of layers of the second build-up layer 124 may sum up to a total of 0 to 8 layers for the conductive patterns and dielectric layers. In some alternative embodiments, at least one of the first build-up layer 123 and the second build-up layer 124 may be omitted. In some embodiments, the number of layers in the first build-up layer 123 is equal to the number of layers in the second build-up layer 124. In some alternative embodiments, the total number of the first build-up layer 123 and the second build-up layer 124 may be different. In some embodiments, the total number of layers of the first build-up layer 123 and the second build-up layer 124 in the circuit substrate 120 is less than the total number of layers of the build-up layer in the related circuit structure (e.g., related circuit board structure) which may be 28 to 36 layers. Therefore, in some examples, the circuit substrate 120 may be also called a semi-finished circuit substrate or a semi-finished circuit carrier.

In some embodiments, a first mask layer 125 is disposed on the outermost first dielectric layer 1231 to cover the outermost first conductive patterns 1232, and a second mask layer 126 is disposed on the outermost second dielectric layer 1241 to cover the outermost second conductive patterns 1242. As shown in FIG. 1A, the first mask layer 125 is disposed on a first side 120a of the circuit substrate 120, and the second mask layer 126 is disposed on a second side 120b of the circuit substrate 120 opposite to the first side 120a. As shown in FIG. 1A, the first mask layer 125 includes a plurality of openings O1 that partially expose the outermost second conductive patterns 1242 for further electrical connection, and the second mask layer 126 includes a plurality of openings O2 that partially expose the outermost second conductive patterns 1242 for further electrical connection. In some embodiments, the materials of the first and second mask layers 125 and 126 may be or may include a chemical composition of silica, barium sulfate and epoxy resin, and/or the like. The first and second mask layers 125 and 126 may serve as solder masks. The first and second mask layers 125 and 126 may be selected to prevent short, corrosion or contamination of the circuit pattern and protect circuits of the circuit substrate 120 from external impacts and chemicals, and may be selected to withstand the temperatures of molten conductive materials (e.g., solders, metals, and/or metal alloys) to be subsequently disposed within the openings O1 and O2. In some embodiments, the dimension of the opening O1 is greater than the dimension of the opening O2.

Referring to FIG. 1B, a redistribution structure 100 is formed on the second mask layer 126 and electrically connected to the second build-up layer 124. In some embodiments, the formation of the redistribution structure 100 includes at least the following steps. Firstly, first conductive vias V1 are formed on the second mask layer 126 and penetrating the second mask layer 126 through the openings O2 to be in contact with the second conductive patterns 1242 exposed by the openings O2. In some embodiments, a seed layer (not shown) is initially and conformally formed on the second mask layer 126. The seed layer may be a Ti/Cu bilayer, a copper layer, or other suitable metal layer, and may be deposited using any suitable deposition technique such as physical vapor deposition (PVD), e.g., sputtering, evaporation, etc. Next, a patterned photoresist layer having openings (also not shown) may be formed to partially cover the seed layer using such as a spin-coating process, lithography and etching processes, or the like. A conductive material may be formed on the seed layer within the openings of the patterned photoresist layer. The conductive material may include copper, titanium, tungsten, aluminum, another metal, the like, or a combination thereof, and may be formed by such as electroplating or electroless plating, or the like. Subsequently, the patterned photoresist layer may be removed by a suitable removal process such as ashing, stripping, or the like. After the removal of the patterned photoresist layer, those portions of the seed layer that were covered by the patterned photoresist layer may be removed by any suitable process (e.g., wet etching, dry etching, or the like), and the conductive material may serve as an etch mask during the removal process of the seed layer. The remaining portions of the seed layer and the conductive material thereon collectively form the first conductive vias V1.

As shown in FIG. 1B, the first conductive vias V1 cover a portion of the second mask layer 126 and penetrate the second mask layer 126 through the openings O2 to be in contact with the outermost second conductive patterns 1242. In other words, the first conductive vias V1 are in contact with the second mask layer 126 and the second conductive patterns 1242. From another point of view, the first conductive vias V1 are in contact with the outermost second conductive patterns 1242 to electrically connect the redistribution structure 100 and the second build-up layer 124 of the circuit substrate 120. In a top-down view, the first conductive vias V1 may be formed in a desired shape, such as a circular, oval, square, rectangular, or polygonal shape, although any desired shape may alternatively be formed.

In some embodiments, after forming the first conductive vias V1, a first dielectric layer PM1 is formed over the second mask layer 126 to cover the first conductive vias V1. For example, a dielectric material is formed on the second mask layer 126 by a process such as lamination, spin-coating, chemical vapor deposition (CVD), a combination thereof, etc. The dielectric material may be or may include polybenzoxazole (PBO), polyimide (PI), benzocyclobutene (BCB), prepreg, Ajinomoto build-up film (ABF), an oxide (e.g., silicon oxide), a nitride (e.g., silicon nitride), phosphosilicate glass (PSG), borosilicate glass (BSG), boron-doped phosphosilicate glass (BPSG), a molding compound, a photosensitive polymer material, a combination thereof, and/or the like. The dielectric material is optionally planarized, such as by a chemical mechanical polish (CMP) or a mechanical grinding, to form the first dielectric layer PM1. For example, the first dielectric layer PM1 laterally covers the first conductive vias V1. In details, the first dielectric layer PM1 laterally covers the sidewalls of the first conductive vias V1. From another point of view, since the first conductive vias V1 penetrate through the second mask layer 126, the first conductive vias V1 are laterally covered by the first dielectric layer PM1 and the second mask layer 126. In some embodiments, the top surface Ps1 of the first dielectric layer PM1 is substantially leveled with the top surfaces Vs1 of the first conductive vias V1. In some embodiments, the first conductive via V1 includes substantially vertical sidewalls relative to the top surface of the underlying second mask layer 126. In some embodiments, the first conductive vias V1 embedded in the first dielectric layer PM1 are viewed as the first level of the redistribution structure 100.

Continue to FIG. 1B, first conductive patterns RDL1, second conductive vias V2, and a second dielectric layer PM2 are then formed on the first conductive vias V1 and the first dielectric layer PM1. The first conductive patterns RDL1 and the second conductive vias V2 are collectively viewed as a redistribution layer at the second level to provide additional routing. In some embodiments, the first conductive patterns RDL1 are initially formed on the first conductive vias V1 and the first dielectric layer PM1 using the processes similar to the formation of the first conductive vias V1. The first conductive patterns RDL1 may include metal lines and/or pads. Next, after forming the first conductive patterns RDL1, the second conductive vias V2 are formed on the first conductive patterns RDL1. The material of the second conductive vias V2 may be similar to the first conductive patterns RDL1 and/or the first conductive vias V1. In some embodiments, the formation of the second conductive vias V2 includes at least the following steps. A patterned photoresist layer with openings (not shown) is formed over the first dielectric layer PM1 to partially cover the first conductive patterns RDL1. The openings of the patterned photoresist layer accessibly reveal desired parts of the first conductive patterns RDL1. Next, the conductive material may be formed on the first conductive patterns RDL1 within the openings of the patterned photoresist layer by such as electroplating, electroless plating, or other suitable deposition process. Subsequently, the patterned photoresist layer may be removed. The conductive material plated on the first conductive patterns RDL1 may form the second conductive vias V2. In some embodiments, after forming the second conductive vias V2, the second dielectric layer PM2 is formed on the first dielectric layer PM1 to cover the second conductive vias V2 and the first conductive patterns RDL1 using the processes similar to the formation of the first dielectric layer PM1. The material of the second dielectric layer PM2 may be similar to or different from the first dielectric layer PM1 depending on product and process requirements.

In some alternative embodiments, the first dielectric layer PM1 having openings is formed over the second mask layer 126, and then the first conductive vias V1 are formed on the second conductive patterns 1242 within the openings of the first dielectric layer PM1. In these embodiments, the first conductive via V1 includes inclined sidewalls relative to the top surface of the underlying second mask layer 126. The first conductive patterns RDL1 and the first conductive vias V1 may be formed during the same step. Under this scenario, the planarization process may be omitted, and there is no visible interface between the first conductive pattern RDL1 and the corresponding and underlying first conductive via V1.

Still referring to FIG. 1B, additional conductive patterns (e.g., second conductive patterns RDL2, third conductive patterns RDL3, fourth conductive patterns RDL4, fifth conductive patterns RDL5, and sixth conductive patterns RDL6), conductive vias (e.g., third conductive vias V3, fourth conductive vias V4, fifth conductive vias V5, and sixth conductive vias V6), and dielectric layers (e.g., third dielectric layer PM3, fourth dielectric layer PM4, fifth dielectric layer PM5, sixth dielectric layer PM6, and seventh dielectric layer PM7) may be formed over the second conductive vias V2 and the second dielectric layer PM2 to provide additional routing. In details, the second conductive patterns RDL2 and the third conductive vias V3 are collectively viewed as a redistribution layer at the third level of the redistribution structure 100, the third conductive patterns RDL3 and the fourth conductive vias V4 are collectively viewed as a redistribution layer at the fourth level of the redistribution structure 100, the fourth conductive patterns RDL4 and the fifth conductive vias V5 are collectively viewed as a redistribution layer at the fifth level of the redistribution structure 100, the fifth conductive patterns RDL5 and the sixth conductive vias V6 are collectively viewed as a redistribution layer at the sixth level of the redistribution structure 100, and the sixth conductive patterns RDL6 and the seventh conductive vias V7 are collectively viewed as a redistribution layer at the seventh level of the redistribution structure 100. The dielectric layers and the redistribution layers may be alternately formed, and may be formed using processes and materials similar to those used for the underlying dielectric layer or the underlying redistribution layers. The steps of forming the conductive patterns, the conductive vias, and the dielectric layers may be repeated to form the redistribution structure 100. It is noted that the redistribution structure 100 shown in FIG. 1A is merely an example and may have any suitable number of dielectric layers or redistribution layers. For example, the redistribution structure 100 includes N-th conductive vias and (N−1)-th conductive patterns that are embedded by an N-th dielectric layer, and N-th conductive patterns that are embedded by an (N+1)-th dielectric layer, where N is a positive integer. In other embodiments, the redistribution structure 100 is formed in a different process from described herein. Further, as shown in FIG. 1B, the redistribution layers including the conductive vias and the conductive patterns are formed within the circuit region CR.

Still referring to FIG. 1B, in some embodiments, the bottommost conductive via (e.g., the first conductive via V1) has a critical dimension greater than a critical dimension of the topmost conductive via (e.g., the sixth conductive via V6). For example, the critical dimension (or diameter) Vd1 of the first conductive via V1 is greater than the critical dimension (or diameter) Vd6 of the sixth conductive via V6. For example, the critical dimension Vd1 of the first conductive via V1 is in a range of about 30 μm and about 1000 μm. The critical dimension Vd6 of the sixth conductive via V6 may range from about 0.5 μm to about 50 μm. As shown in FIG. 1B, the critical dimensions (or diameters) of the sixth conductive via V6, the fifth conductive via V5, the fourth conductive via V4, the third conductive via V3 and the second conductive via V2 are the same. However, it is noted that the arrangement of the conductive vias V1-V6 shown in FIG. 1B is merely an example. In some alternative embodiments, the diameters of the conductive vias are gradually reduced layer by layer from the bottommost level of the redistribution structure 100 to the topmost level of the redistribution structure 100.

Further, it is also noted that the arrangement of the redistribution layers of the redistribution structure 100 shown in FIG. 1B is merely an example. In some embodiments, the redistribution structure 100 is a fan-out structure. The redistribution layers in the redistribution structure 100 may be fan-out from the topmost level (e.g., seventh conductive pattern RDL7) to the bottommost level (e.g., first conductive pattern RDL1). For example, the spacing SP1 of the first conductive patterns RDL1 at the bottommost level of the redistribution structure 100 is greater than the spacing SP6 of the sixth conductive patterns RDL6 at the topmost level of the redistribution structure 100. For example, the spacing SP1 of the first conductive patterns RDL1 is in a range of about 30 μm and about 1000 μm. The spacing SP6 of the sixth conductive patterns RDL6 at the topmost level of the redistribution structure 100 may range from about 0.1 μm to about 30 μm.

In some embodiments, at least the topmost dielectric layer (e.g., the seventh dielectric layer PM7) is formed differently from the underlying dielectric layer (e.g., the sixth dielectric layer PM6) or any other dielectric layers below the topmost dielectric layer. For example, the topmost dielectric layer (e.g., the seventh dielectric layer PM7) is formed of a polymer material such as PBO, PI, or the like, and the dielectric layers below the topmost dielectric layer may be formed of a different material, such as by being formed of an ABF or a prepreg material. For example, the seventh dielectric layer PM7 and the sixth dielectric layer PM6 are formed of the same polymer material such as PBO, PI, or the like, and other dielectric layers below the sixth dielectric layer PM6 (e.g., fifth dielectric layer PM5, fourth dielectric layer PM4, third dielectric layer PM3, second dielectric layer PM2 and first dielectric layer PM1) are formed of a different material, such as by being formed of an ABF. Under this scenario, the structural stability of the redistribution structure 100 is improved, thus reducing the possibility of failure during subsequent manufacturing processes. In some embodiments, the topmost dielectric layer (e.g., the seventh dielectric layer PM7) has a larger thickness than the underlying dielectric layer (e.g., the sixth dielectric layers PM6). However, any combination of materials and thicknesses may be utilized.

Still referring to FIG. 1B, in some embodiments, the topmost dielectric layer (e.g., the seventh dielectric layer PM7) includes openings OP7 accessibly exposing at least a portion of the underlying conductive pattern (e.g., the sixth conductive pattern RDL6) for further electrical connection. As mentioned, the redistribution layers including the conductive vias and the conductive patterns are formed within the circuit region CR, and thus the openings OP7 of the topmost dielectric layer (e.g., the seventh dielectric layer PM7) are distributed within the circuit region CR.

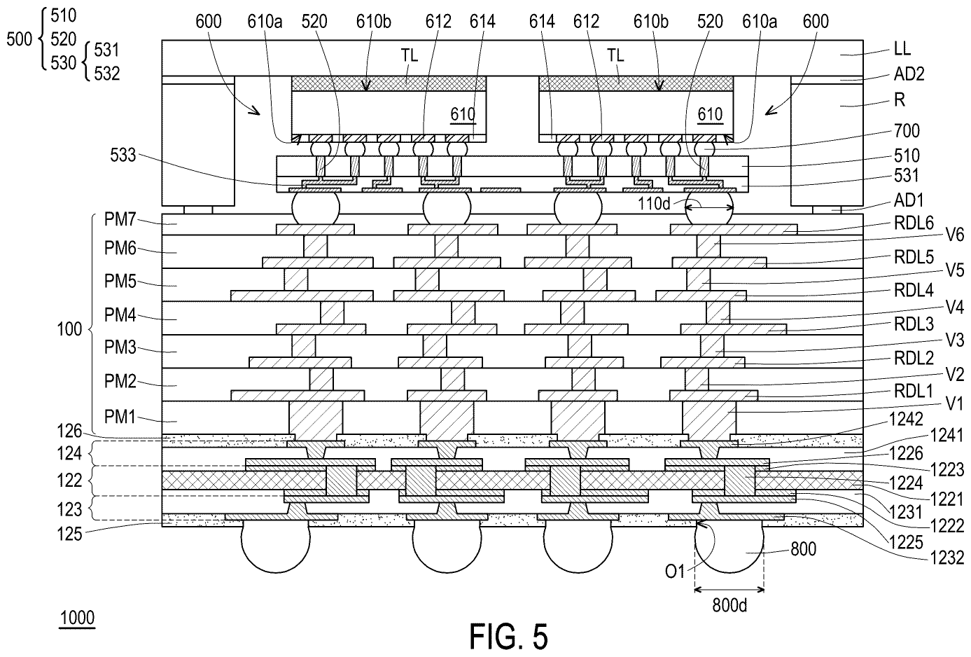

Referring to FIG. 1C, a plurality of conductive terminals 110 are formed in the openings OP7 of the seventh dielectric layer PM7 over the sixth conductive patterns RDL6 for further electrical connection. The conductive terminals 110 are in physically and electrically connected with the outermost sixth conductive patterns RDL6 of the redistribution structure 100. In some embodiments, a pitch 110P of the adjacent conductive terminals 110 is less than 130 μm. In certain embodiments, the pitch 110P of the adjacent conductive terminals 110 is less than 10 μm. It is noted that the pitch of the conductive terminals 110 may be adjusted depending on I/O connectors of a semiconductor device (e.g., the interposer 500 shown in FIG. 5) that is to be mounted thereon. In some embodiments, the conductive terminals 110 are controlled collapse chip connection (C4) bumps. In some embodiments, the conductive terminals 110 are formed by such as solder plating or ball placement. In some embodiments, the conductive terminals 110 includes solder bump formed by landing solder balls in the openings OP7 of the seventh dielectric layer PM7, and then reflowing the solder material. In some embodiments, the respective conductive terminal 110 includes a lead-free pre-solder layer, Sn—Ag, or solder material including alloys of tin, lead, nickel, bismuth, silver, copper, combinations thereof, or the like. In some embodiments, the conductive terminals 110 are formed by plating a solder layer with lithography process followed by reflowing process to reshape the solder layer into the desired bump shapes.

Referring to FIG. 1D, a singulation process is performed to separate the structure shown in FIG. 1C into a plurality of substrate structures 10. The singulation process may be performed using any suitable dicing tool (e.g., a blade, a saw, a laser drill, an etching process, combinations thereof, etc.) to cut through and/or remove materials of the different layers of the structure. For example, the dicing tool cuts along the scribe line regions SR to separate the circuit regions CR so as to form the substrate structures 10. In some embodiments, the redistribution structure 100, the underlying second mask layer 126, the underlying circuit substrate 120 and the underlying first mask layer 125 are cut through to form substantially coterminous sidewalls 10s of the substrate structure 10. In detail, as shown in FIG. 1D, the seventh dielectric layer PM7, the sixth dielectric layer PM6, the fifth dielectric layer PM5, the fourth dielectric layer PM4, the third dielectric layer PM3, second dielectric layer PM2, the first dielectric layer PM1, the second mask layer 126, the second dielectric layer 1241, the core dielectric layer 1221, the first dielectric layer 1231 and the first mask layer 125 are cut through to form the substantially coterminous sidewalls 10s of the substrate structure 10. That is, the substantially coterminous sidewalls 10s of the substrate structure 10 includes the sidewalls of the seventh dielectric layer PM7, the sixth dielectric layer PM6, the fifth dielectric layer PM5, the fourth dielectric layer PM4, the third dielectric layer PM3, second dielectric layer PM2, the first dielectric layer PM1, the second mask layer 126, the second dielectric layer 1241, the core dielectric layer 1221, the first dielectric layer 1231 and the first mask layer 125. In other words, the sidewalls of the seventh dielectric layer PM7, the sixth dielectric layer PM6, the fifth dielectric layer PM5, the fourth dielectric layer PM4, the third dielectric layer PM3, second dielectric layer PM2, the first dielectric layer PM1, the second mask layer 126, the second dielectric layer 1241, the core dielectric layer 1221, the first dielectric layer 1231 and the first mask layer 125 are substantially leveled with each other. After the singulation process, the substrate structures 10 may be placed on a tray cassette awaiting to be transferred to the next station. As mentioned, the circuit substrate 120 is provided in a panel format, and thus the substrate structure 10 is manufactured using a panel form fabrication process.

As shown in FIG. 1D, the respective substrate structure 10 includes the redistribution structure 100, the circuit substrate 120 disposed over a first side 100a of the redistribution structure 100, and the conductive terminals 110 distributed on a second side 100b of the redistribution structure 100 opposite to the first side 100a. The circuit substrate 120 is electrically connected to the redistribution structure 100 through the first conductive vias V1 at the first side 100a of the redistribution structure 100, and the first conductive vias V1 are formed through the openings O2 of the second mask layer 126 and on the second build-up layer 124. The conductive terminals 110 are electrically coupled to the circuit substrate 120 through the redistribution structure 100.

In some embodiments, the first dielectric layer PM1 is in contact with the second mask layer 126 of the circuit substrate 120. In some embodiments, the second mask layer 126 is located between the first dielectric layer PM1 and the second dielectric layer 1241. In some embodiments, the redistribution structure 100 is disposed over the second side 120b of the circuit substrate 120. In some embodiments, the redistribution structure 100 and the second mask layer 126 are disposed over the second side 120b of the circuit substrate 120, and the first mask layer 125 is disposed over the first side 120a of the circuit substrate 120 opposite to the second side 120b. In detail, as shown in FIG. 1D, the substrate structure 10 is redistribution structure-free at the first side 120a of the circuit substrate 120. That is, during the formation of the substrate structure 10, the redistribution structure 100 is only formed over the second side 120b with no redistribution structure formed over the first side 120a. In other words, during the formation of the substrate structure 10, the redistribution structure 100 is formed over the second side 120b, while leaving the first side 120a free of any redistribution structure. In some embodiments, a critical dimension of the conductive features in the redistribution structure 100 close to the first side 100a is greater than that of the conductive features in the redistribution structure 100 away from the first side 100a (or close to the second side 100b). For example, the spacing SP1 of the first conductive patterns RDL1 close to the first side 100a of the redistribution structure 100 is greater than the spacing SP6 of the sixth conductive patterns RDL6 close to the second side 100b of the redistribution structure 100. For example, the critical dimension of the first conductive via V1 close to the first side 100a of the redistribution structure 100 is greater than the critical dimension of the sixth conductive via V6 close to the second side 100b of the redistribution structure 100.

By forming the redistribution structure 100 over only one side (e.g., second side 120b) of the circuit substrate 120 to allow an asymmetric distribution of dielectric layers on opposite sides of the substrate structure 10, the resulted substrate structure 10 has a reduced thickness and a high modulus. Further, compared to related circuit structure, because fewer layers are included in the build-up layers of the circuit substrate 120, the manufacturing cost of the resulted substrate structure 10 is reduced. In some embodiments, since the redistribution structure 100 is formed on the circuit substrate 120 and then the conductive terminals 110 are formed on the redistribution structure 100 by solder plating, a laser drilling process and a ball placement process are omitted to simplify the manufacturing steps and lower the manufacturing cost of the resulted substrate structure 10. The warpage of the substrate structure 10 may be reduced by omitting the steps of laser drilling and/or ball placement. As such, the manufacturing method described above may meet the requirements of smaller form factor, lower process costs and prevention of cracking issue causing by high warpage degrees.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure.

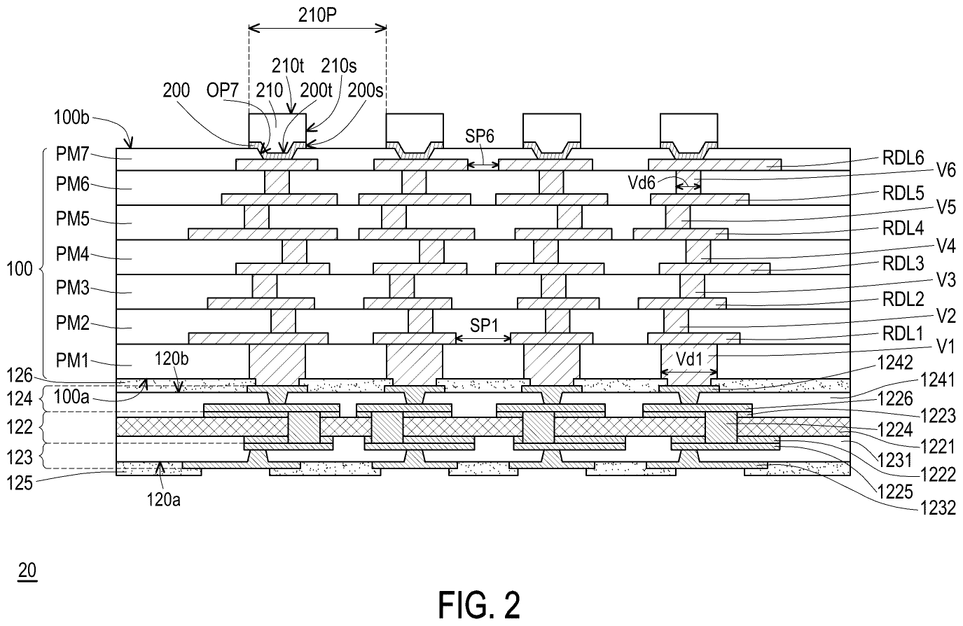

As shown in FIG. 1D, in the substrate structure 10, the conductive terminals 110 are in physical contact with the outermost sixth conductive patterns RDL6 of the redistribution structure 100. However, the disclosure is not limited thereto. In some alternative embodiments, the under-bump metallization (UBM) patterns may be located between the conductive terminals and the outermost conductive patterns. Hereinafter, other embodiments will be described with reference to FIG. 2 to FIG. 4.

FIG. 2 is schematic cross-sectional views of variations of a substrate structure in accordance with some embodiments. The substrate structure 20 illustrated in FIG. 2 is similar to the substrate structure 10 illustrated in FIG. 1D, hence the same reference numerals are used to refer to the same or liked parts, and its detailed description will be omitted herein. The differences between the substrate structure 20 and the substrate structure 10 will be described below.

Referring to FIG. 2, UBM patterns 200 and conductive terminals 210 are sequentially formed in the openings OP7 of the topmost dielectric layer (e.g., the seventh dielectric layer PM7) for further electrical connection. The UBM pattern 200 may be a single layer or may include a plurality of layers conformally formed in the openings OP7 and on the topmost dielectric layer (e.g., the seventh dielectric layer PM7). In some embodiments, the UBM pattern 200 has a recessed top surface 200t corresponding to the corresponding opening OP7. For example, the UBM pattern 200 includes multiple layers of conductive materials, such as a layer of titanium, a layer of copper, and a layer of nickel. In such embodiments, the layer of titanium is conformally formed on the topmost dielectric layer (e.g., the seventh dielectric layer PM7) to be in physical and electrical contact with the outermost conductive patterns (e.g., the sixth conductive patterns RDL6) exposed by the openings OP7 of the topmost dielectric layer (e.g., the seventh dielectric layer PM7), and then the layer of copper and the layer of nickel are sequentially formed on the layer of titanium. In some embodiments, the UBM pattern 200 includes an arrangement of titanium/titanium tungsten/copper, an arrangement of copper/nickel/gold, or other materials or layers of material. Each layer of the UBM pattern 200 may be formed by such as plating sputtering, evaporation, or other suitable deposition process depending upon the desired materials. After deposition of the desired layers, lithography and etching processes may be performed to form the UBM pattern 200 in a desired shape. For example, the shape of the UBM pattern 200 may be circular, oval, square, rectangular, polygon, etc.

Continued on FIG. 2, the conductive terminals 210 are formed on the UBM patterns 200. In some embodiments, the respective conductive terminal 210 includes a pre-solder layer and a solder layer formed on the pre-solder layer. For example, a pre-solder layer is formed on the UBM pattern 200 by plating, sputtering, printing, CVD, or other depositions. The pre-solder layer may be formed of eutectic materials such as an alloy including tin and lead, and/or the like. A solder layer may then be formed by plating, where during the plating the pre-solder layer may serve as a seed layer. The solder layer may be a lead based solder such as Pb or Pb/Sn, a lead free solder such as Sn, Sn/Ag, Sn/Ag/Cu, or other eutectic materials used as lead free solder. In some embodiments, before forming the pre-solder layer, a mask layer (e.g., photoresist) is formed and patterned to have openings, so that portions of the UBM patterns 200 are exposed by the openings. Next, the pre-solder layer and the solder layer may be plated in the openings of the mask layer and over the UBM patterns 200. Subsequently, the mask layer is removed.

In some embodiments, a reflow process is not performed on the pre-solder layer and the solder layer to form the conductive terminals 210. Under this scenario, the sidewall 210s of the conductive terminal 210 remains to be substantially vertical, and the top surface 210t of the conductive terminal 210 connected to the sidewalls 210s remains to be substantially planar. As shown in FIG. 2, the sidewall 210s of the conductive terminal 210 is substantially leveled with the sidewall 200s of the underlying UBM pattern 200 on the top surface of the outermost one of the dielectric layers (e.g., the seventh dielectric layer PM7). However, the disclosure is not limited thereto, and other methods for forming the conductive terminals 210 may be used. For example, in some alternative embodiments, the conductive terminals 210 are formed of non-reflowable materials that do not melt under the melting temperature of solder material. Under this scenario, the sidewalls 210s of the conductive terminals 210 remain to be substantially vertical and the top surfaces 210t of the conductive terminal 210 remain to be substantially planar after the reflow process.

In some embodiments, a pitch 210P of the adjacent conductive terminals 210 is less than 130 μm. In certain embodiments, the pitch 210P of the adjacent conductive terminals 210 is less than 10 μm. It is noted that the pitches of the conductive terminals 210 may be adjusted depending on I/O connectors of a semiconductor device (e.g., the interposer 500 shown in FIG. 5) that is to be mounted thereon.

In light of the foregoing, the redistribution structure 100 is disposed over only one side (e.g., second side 120b) of the circuit substrate 120 to allow an asymmetric distribution of dielectric layers on opposite sides of the substrate structure 20, the resulted substrate structure 20 has a reduced thickness and a high modulus. Further, compared to related circuit structure, because fewer layers are included in the build-up layers of the circuit substrate 120, the manufacturing cost of the resulted substrate structure 20 is reduced. Since the redistribution structure 100 is formed on the circuit substrate 120 and then the conductive terminals 210 are formed over the redistribution structure 100 by plating, a laser drilling process and a ball placement process are omitted to simplify the manufacturing steps and lower the manufacturing cost of the resulted substrate structure 20. The warpage of the substrate structure 20 may be reduced by omitting the steps of laser drilling and/or ball placement. Further, since the conductive terminals 210 are formed by plating without performing a reflow process, the number of the manufacturing steps of the resulted substrate structure 20 is simplified and the manufacturing cost of the resulted substrate structure 20 is reduces. As such, the manufacturing method of the resulted substrate structure 20 may meet the requirements of smaller form factor, lower process costs and prevention of cracking issue causing by high warpage degrees.

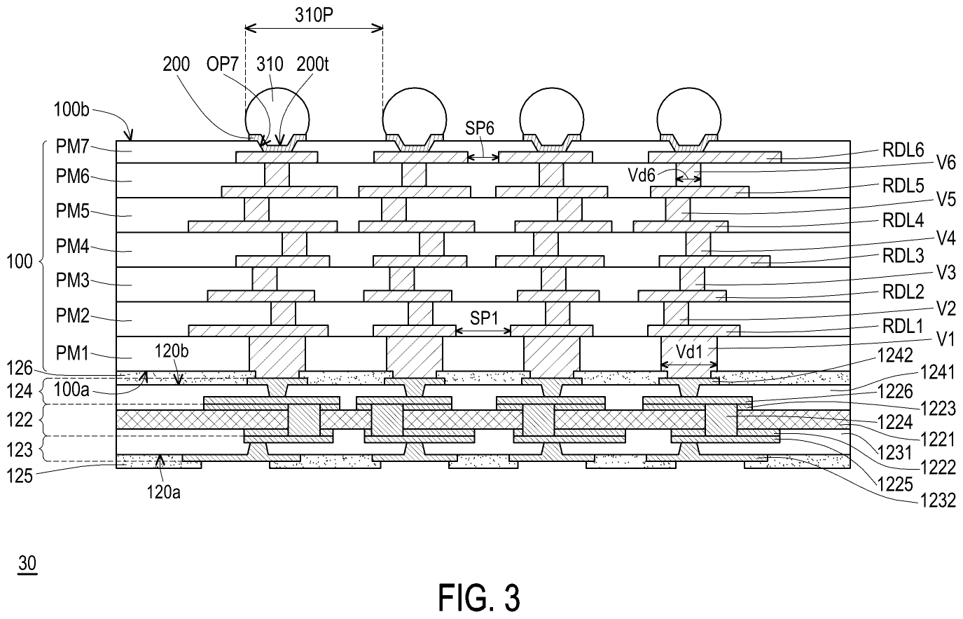

FIG. 3 is schematic cross-sectional views of variations of a substrate structure in accordance with some embodiments. The substrate structure 30 illustrated in FIG. 3 is similar to the substrate structure 20 illustrated in FIG. 2, hence the same reference numerals are used to refer to the same or liked parts, and its detailed description will be omitted herein. The differences between the substrate structure 30 and the substrate structure 20 will be described below.

Referring to FIG. 3, after the UBM patterns 200 are formed, conductive terminals 310 are formed on the recessed top surfaces 200t of the UBM patterns 200. In some embodiments, the respective conductive terminal 310 includes a pre-solder layer and a solder layer formed on the pre-solder layer. For example, a pre-solder layer is formed on the UBM pattern 200 by plating, sputtering, printing, CVD, or other depositions. The pre-solder layer may be formed of eutectic materials such as an alloy including tin and lead, and/or the like. A solder layer may then be formed by plating, where during the plating the pre-solder layer may serve as a seed layer. The solder layer may be a lead based solder such as Pb or Pb/Sn, a lead free solder such as Sn, Sn/Ag, Sn/Ag/Cu, or other eutectic materials used as lead free solder. The pre-solder layer and the solder layer are subjected to a reflow process to form the conductive terminals 310 with the desired bump shapes. Under this scenario, the conductive terminals 210 have rounded top surfaces after the reflow process, as shown in FIG. 3. In some embodiments, before forming the pre-solder layer, a mask layer (e.g., photoresist) is formed and patterned to have openings, so that portions of the UBM patterns 200 are exposed by the openings. Next, the pre-solder layer and the solder layer may be plated in the openings of the mask layer and over the UBM patterns 200. Subsequently, the mask layer is removed.

In some embodiments, a pitch 310P of the adjacent conductive terminals 310 is less than 130 μm. In certain embodiments, the pitch 310P of the adjacent conductive terminals 310 is less than 10 μm. It is noted that the pitches of the conductive terminals 310 may be adjusted depending on I/O connectors of a semiconductor device (e.g., the interposer 500 shown in FIG. 5) that is to be mounted thereon.

In light of the foregoing, the redistribution structure 100 is disposed over only one side (e.g., second side 120b) of the circuit substrate 120 to allow the substrate structure 30 having an asymmetric structure, the resulted substrate structure 30 has a reduced thickness and a high modulus. Further, compared to related circuit structure, because fewer layers are included in the build-up layers of the circuit substrate 120, the manufacturing cost of the resulted substrate structure 30 is reduced. Since the redistribution structure 100 is formed on the circuit substrate 120 and then the conductive terminals 310 are formed over the redistribution structure 100 by plating, a laser drilling process and a ball placement process are omitted to simplify the manufacturing steps and lower the manufacturing cost of the resulted substrate structure 30. The warpage of the substrate structure 30 may be reduced by omitting the steps of laser drilling and/or ball placement. As such, the manufacturing method of the resulted substrate structure 30 may meet the requirements of smaller form factor, lower process costs and prevention of cracking issue causing by high warpage degrees.

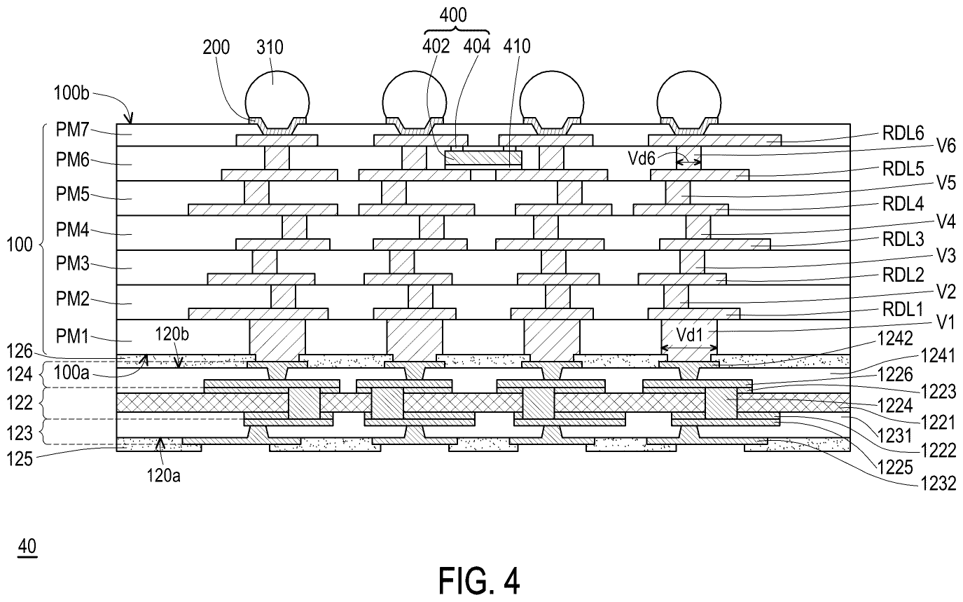

FIG. 4 is schematic cross-sectional views of variations of a substrate structure in accordance with some embodiments. The substrate structure 40 illustrated in FIG. 4 is similar to the substrate structure 30 illustrated in FIG. 3, hence the same reference numerals are used to refer to the same or liked parts, and its detailed description will be omitted herein. The differences between the substrate structure 40 and the substrate structure 30 will be described below.

Referring to FIG. 4, in the substrate structure 40, a die 400 is formed in a sixth dielectric layer PM6′. The die 400 is mounted onto the fifth conductive patterns RDL5 by pick and place processes, for example. In some embodiments, the die 400 is a device die, and the device die is an integrated voltage regulator (IVR) die, an integrated passive device (IPD) die, a memory die such as static random access memory (SRAM) die or the like, which is a component to realize a system on package with a semiconductor device (e.g., the interposer 500 shown in FIG. 5) that is to be mounted thereon. However, the disclosure is not limited thereto. In some alternative embodiments, depending on an arrangement of semiconductor devices that are to be mounted thereon, the die 400 is a bridge die, and the bridge die is a local silicon interconnect (LSI) die which provides a shorter electrical connection path between the semiconductor devices that are to be mounted thereon.

In some embodiments, as shown in FIG. 4, the die 400 includes a substrate 402 and a plurality of conductive patterns 404 on the substrate 402. In some embodiments, the substrate 402 is a semiconductor substrate such as a silicon substrate, or the likes. The die 400 may also include conductive patterns or traces (not shown) in the substrate 402, and the conductive patterns or traces may be electrically connected with the conductive patterns 404 of the die 400. In some embodiments, the conductive patterns or traces may be disposed in or on the substrate 402. In some embodiments, the conductive patterns 404 may be densely arranged, so that the die 400 may provide high density of interconnect elements. In some embodiments, the conductive pattern 404 has a single structure or multiple layered structures. The material of the conductive pattern 404 may include copper, aluminum, a combination thereof, or the like. In some embodiments, the die 400 may be mounted and/or attached onto the fifth conductive patterns RDL5 through an adhesive layer 410 therebetween. The adhesive layer 410 may be a die attach film (DAF). In these embodiments, the die 400 is not directly and/or physically connected with the fifth conductive patterns RDL5 by a conductor. However, the disclosure is not limited thereto. In some alternative embodiments, the die 400 may have through silicon vias, and the die 400 may be bonded to the fifth conductive patterns RDL5 by solder balls to electrically connect with the fifth conductive patterns RDL5 directly. In some embodiments, the die 400 includes an interconnecting structure and may be free of any active and/or passive device(s).

In some embodiments, the formation of the substrate structure 40 includes at least the following steps. After placing the die 400 onto the fifth conductive patterns RDL5, the sixth dielectric layer PM6′ is formed over the fifth dielectric layer PM5 to cover the fifth conductive patterns RDL5, the sixth conductive vias V6 and the die 400. The sixth dielectric layer PM6′ is formed by using the processes similar to the formation of the first dielectric layer PM1. In some embodiments, the sixth dielectric layer PM6′ includes a molding compound such as an epoxy molding compound formed by a molding process. In some alternative embodiments, the sixth dielectric layer PM6′ may include an epoxy, a resin or the like. After forming the sixth dielectric layer PM6′, the sixth conductive patterns RDL6 are formed over the sixth dielectric layer PM6′ which electrically connect with the die 400, the seventh dielectric layer PM7 is formed over the sixth dielectric layer PM6′ to cover the sixth conductive patterns RDL6, and the UBM patterns 200 and the conductive terminals 310 are sequentially formed in the openings OP7 of the seventh dielectric layer PM7 for further electrical connection.

For ease of illustration, FIG. 4 only shows one die 400. However, any person having ordinary skill in the art should understand that, more than one die 400 may be placed in the redistribution structure 100 depending on the product design. According to the description related to FIG. 3 and FIG. 4, any person having ordinary skill in the art should understand that, the die 400 may also be placed and/or embedded into the substrate structure 10 shown in FIG. 1D, or the substrate structure 20 shown in FIG. 2.

FIG. 5 is a schematic cross-sectional view of an application of a substrate structure in accordance with some embodiments.

Referring to FIG. 5, a system package 1000 is provided. In some embodiments, as shown in FIG. 5, the system package 1000 includes the substrate structure 10, an interposer 500 disposed on and connected to the substrate structure 10, and semiconductor dies 600 disposed on and connected to the interposer 500. In some embodiments, the system package 1000 is referred to as a chip-on-wafer-on-substrate package. However, the disclosure is not limited neither by the type nor the number of semiconductor devises connected to the substrate structure. It will be apparent that different types of semiconductor devises may be used to produce system packages including the substrate structure disclosed herein, and all these system packages are intended to fall within the scope of the present description and of the attached claims. For example, System-On-Chip (SoC), Integrated-Fan-Out (InFO) package, Chip-On-Wafer-On-Substrate structure, three-dimensional integrated circuit (3DIC) structure, Package-on-Package (PoP) structure may all be used as the semiconductor device connected to the substrate structure, alone or in combination.

Still referring to FIG. 5, the interposer 500 is coupled to the substrate structure 10 through the conductive terminals 110. In some embodiments, the interposer 500 is placed and in physical contact with the conductive terminals 110, and then a reflow process may be performed to bond the conductive terminals 110 of the substrate structure 10 to the interposer 500. However, any suitable bonding technique may be used to couple the interposer 500 and the substrate structure 10. The substrate structure 10 may be similar to the substrate structure 10 described in FIG. 1D. The substrate structure 10 of the system package 1000 may be replaced with any one of the substrate structures discussed elsewhere in the disclosure (e.g., the substrate structure 20 shown in FIG. 2, the substrate structure 30 shown in FIG. 3, or the substrate structure 40 shown in FIG. 4).

In some embodiments, as shown in FIG. 5, the interposer 500 includes a substrate 510, through substrate vias 520 formed in the substrate 510, and an interconnection structure 530 formed on a side of the substrate 510. The substrate 510 may include elementary semiconductor such as silicon. The substrate 510 may be doped as needed.

In some embodiments, the interconnection structure 530 is disposed on the substrate 510 and includes a dielectric layer 531 and conductive traces 533 extending through the dielectric layer 531. For simplicity, the dielectric layer 531 is illustrated as a single dielectric layer and the conductive traces 533 are illustrated as embedded in the dielectric layer 531. Nevertheless, from the perspective of the manufacturing process, the dielectric layer 531 is constituted by at least two dielectric layers. The conductive traces 533 may be sandwiched between two adjacent dielectric layers. Some of the conductive traces 533 may extend vertically through the dielectric layer 531 to establish electrical connection between different metallization tiers of the interconnection structure 530. In some embodiments, the outermost dielectric layer 531 (when multiple dielectric layers are presented in the dielectric layer 531) may be patterned to expose the underlying conductive traces 533. In some embodiments, the material of the dielectric layer 531 includes polyimide, epoxy resin, acrylic resin, phenol resin, BCB, PBO, or any other suitable polymer-based dielectric material. The dielectric layer 531, for example, may be formed by suitable fabrication techniques such as spin-on coating, CVD, plasma-enhanced chemical vapor deposition (PECVD), or the like. In some embodiments, the material of the conductive traces 533 includes aluminum, titanium, copper, nickel, tungsten, or alloys thereof. The conductive traces 533 may be formed by, for example, electroplating, deposition, and/or photolithography and etching. It should be noted that the number of the dielectric layers 531 and the number of the conductive traces 533 illustrated in FIG. 5 are merely for illustrative purposes, and the disclosure is not limited thereto. In some alternative embodiments, fewer or more layers of the dielectric layers 531 or conductive traces 533 may be formed depending on the circuit design.

As illustrated in FIG. 5, the through substrate vias 520 (also called “through silicon vias” in some examples) are formed in the substrate 510 to provide dual-side electrical connection. In some embodiments, one end of the through substrate via 520 is connected to the conductive traces 533 of the interconnection structure 530 and the other end is connected to the semiconductor dies 600 via conductive terminal 700. In some embodiments, the material of the through substrate vias 520 includes one or more metals. For example, the metal material of the through substrate vias 520 includes copper, titanium, tungsten, aluminum, combinations thereof, or the like.

In some embodiments, the interposer 500 is a silicon interposer. However, the disclosure is not limited thereto. In some alternative embodiments, the interposer 500 may be an organic interposer. In some embodiments, the interposer 500 is an active interposer that contains at least one functional device or integrated circuit device included in the interconnection structure 530. Such active interposer is referred to as a “device-containing silicon interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer 500 is a passive interposer, which is used to convey a lack of a functional device or integrated circuit device. Such passive interposer is referred to as a “device-free silicon interposer” in some examples.

Continued on FIG. 5, the semiconductor dies 600 are coupled to the interposer 500 through conductive terminals 700. In some embodiments, the semiconductor dies 600 are placed over the interposer 500 by such as a pick-and-place process, a flip-chip process, or other suitable techniques. In some embodiments, the semiconductor dies 600 are placed over the interposer 500, and then a reflow process may be performed to bond the semiconductor dies 600 to the interposer 500 through the conductive terminals 700. However, any suitable bonding technique may be used to couple the semiconductor dies

### 600 and the Interposer 500.

As illustrated in FIG. 5, each semiconductor die 600 may include a semiconductor substrate 610, contact pads 612 on an active surface 610a of the semiconductor substrate 610 and a passivation layer 614 laterally covering the contact pads 612. In some embodiments, the semiconductor substrate 610 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 610 has active components (e.g., transistors or the like) and passive components (e.g., resistors, capacitors, inductors, or the like) formed therein.

In some embodiments, the contact pads 612 include aluminum pads, copper pads, or other suitable metal pads. As illustrated in FIG. 5, the passivation layer 614 extends over the active surface 610a of the semiconductor substrate 610. In some embodiments, the passivation layer 614 is formed with openings revealing the contact pads 612. In some embodiments, the passivation layer 614 may be a single layer or a multi-layered structure, including a silicon oxide layer, a silicon nitride layer, a silicon oxy-nitride layer, a dielectric layer formed by other suitable dielectric materials, or combinations thereof. The contact pads 612 may be at least partially exposed by the openings of the passivation layer 614.

In some embodiments, each of the semiconductor dies 600 has a single function (e.g., a logic die (such as a central processing unit (CPU) die, a graphic processing unit (GPU) die, a micro control unit (MCU) die, an input-output (I/O) die, a baseband (BB) die, or an application processor (AP) die), memory die (such as a dynamic random access memory (DRAM) die, a static random access memory (SRAM) die, a hybrid memory cube (HMC) die, or a high bandwidth memory (HBM) die), etc.), or has multiple functions (e.g., a system on a chip (SoC), an application-specific integrated circuit (ASIC), etc.). In some embodiments, the semiconductor dies 600 have different functions and properties. It is appreciated that dies diced from different semiconductor wafers may have different properties and functions. Accordingly, in some embodiments that the semiconductor dies 600 have different functions, the semiconductor dies 600 are singulated from different semiconductor wafers. In some alternative embodiments, the semiconductor dies 600 have the same function and property, and are singulated from the same semiconductor wafer. That is to say, in the system package 1000, the semiconductor dies 600 are different types of semiconductor dies or the same type of semiconductor die. In an embodiment, one of the semiconductor dies 600 is a SoC, and another of the semiconductor dies 600 is a HBM die. Furthermore, in some embodiments, the semiconductor dies 600 are in different sizes (e.g., different heights and/or surface areas). In some alternative embodiments, the semiconductor dies 600 may be in the same size (e.g., same heights and/or surface areas). That is to say, in the system package 1000, the semiconductor dies 600 are in different sizes or in the same size. Further, as shown in FIG. 5, although two semiconductor dies 600 are presented in the system package 1000 for illustrative purposes, those skilled in the art can understand that the number of the semiconductor dies 600 may be more than or less than what is depicted in FIG. 5, and may be designated based on demand and/or design layout.

In some embodiments, the conductive terminals 700 are micro-bumps installed on the through substrate vias 520 and/or the contact pads 612. In some embodiments, the semiconductor die 600 is disposed with the active surface 610a (the surface on which the contact pads 612 are formed) facing the interposer 500. That is, the rear surface 610b of the semiconductor substrate 610 opposite to the active surface 610a faces away from the interposer 500.

Still referring to FIG. 5, the system package 1000 further includes a plurality of conductive terminals 800 in the openings O1 of the first mask layer 125 over the first build-up layer 123. The conductive terminals 800 are electrically connected to the outermost first conductive patterns 1232 in the first build-up layer 123 of the circuit substrate 120. In some embodiments, the conductive terminal 800 has a critical dimension greater than a critical dimension of the conductive terminal 110. For example, the critical dimension (or diameter) 800d of the conductive terminal 800 is greater than the critical dimension (or diameter) 110d of the conductive terminal 110. The conductive terminals 800 may be ball grid array (BGA) connectors, solder balls, metal pillars, and/or the like. In some embodiments, the conductive terminals 800 are made of a conductive material with low resistivity, such as Sn, Pb, Ag, Cu, Ni, Bi, or an alloy thereof. In some embodiments, the conductive terminals 800 are formed by a mounting process and a reflow process. In some embodiments, as shown in FIG. 5, the openings O1 of the first mask layer 125 are filled with the conductive terminals 800 and the top surface of the first mask layer 125 are covered by the conductive terminals 800 while the conductive terminals 800 are separated from each other. However, the disclosure is not limited thereto. In some alternative embodiments, the top surface of the e first mask layer 125 may not be partially covered by the conductive terminals 800. For example, the openings O1 of the first mask layer 125 may be partially filled with the conductive terminals 800. That is, a gap may be formed between the conductive terminal 800 and the first mask layer 125. In certain embodiments, the conductive terminals 800 are available to be mounted onto additional electrical components (e.g., circuit carrier, system board, mother board, etc.). In some alternative embodiments, pads may be formed in the openings O1 of the first mask layer 125 between the conductive terminals 800 and the outermost first conductive patterns 1232.

Still referring to FIG. 5, the system package 1000 further includes a stiffener ring R, an adhesive layer AD1, a lid layer LL, an adhesive layer AD2 and a thermal interface material (TIM) layer TL. However, the disclosure is not limited thereto. In some alternative embodiments, the system package 1000 may include the stiffener ring R and the adhesive layer AD1 without having the lid layer LL, the adhesive layer AD2 and the TIM layer TL.

In some embodiments, the stiffener ring R is adhered on the substrate structure 10 by the adhesive layer AD1. In some embodiments, the stiffener ring R has a quadrangular ring-like shape in the plane view such as the top view or the bottom view, the disclosure is not limited thereto. In some alternative embodiments, the pattern of the stiffener ring R may be designed based on the various designs. Noted that the stiffener ring R is attached on the substrate structure 10 and surrounds the interposer 500 and the semiconductor dies 600 to constrain the substrate structure 10 in order to prevent its warpage or other movement relative to the interposer 500 and the semiconductor dies 600, which may be caused by thermal cycling during package assembly, reliability testing, or field operation. The warpage and stress in the dies or package may lead to die performance degradation or package failure.

In some embodiments, the stiffener ring R is formed of a rigid yet flexible material. In one exemplary embodiment, the stiffener ring R is formed from a metal material with high thermal conductivity (k), such as steel, stainless steel, copper, aluminum, copper tungsten, the like, or combinations thereof. In another embodiment, the stiffener ring R includes a ceramic material. In yet another embodiment, the stiffener ring R includes a silicon containing material. In yet another embodiment, the stiffener ring R includes a composite alloy. In yet another embodiment, the stiffener ring R includes a plastic material. In some embodiments, the material of the stiffener ring R is typically selected to have a CTE the same as or sufficiently similar to the substrate structure 10 in order to apply a counter force to the substrate structure 10 and reduce the bow of the system package 1000 to within tolerances accepted in the industry. For example, the CTE of the stiffener ring R is smaller than 25 ppm/° C., such as 17 ppm/° C., and the CTE of the substrate structure 10 is in a range of 8 ppm/° C. to 25 ppm/° C., such as 17 ppm/° C. In some embodiments, the adhesive layer AD1 includes any suitable adhesive, epoxy, die attach film (DAF), or the like. Alternatively, the adhesive layer AD1 may be a thermally conductive material.

As shown in FIG. 5, the surface S3 (i.e., the illustrated top surface) of the stiffener ring R is higher than the rear surface 610b of the semiconductor substrate 610. However, the disclosure is not limited thereto. In some alternative embodiments, the surface S3 of the stiffener ring R may be lower than the rear surface 610b of the semiconductor substrate 610, or may be laterally aligned with the rear surface 610b of the semiconductor substrate 610.

In some embodiments, the lid layer LL is adhered on the surface S3 of the stiffener ring R by the adhesive layer AD2. The lid layer LL may be coupled to the stiffener ring R to increase the rigid of the stiffener ring R, thereby reducing the warpage of the system package 1000. In addition, the lid layer LL may overlay the semiconductor dies 600 to prevent the electromagnetic interference (EMI). In some embodiments, the lid layer LL is formed from a metal material with high thermal conductivity (k), such as steel, stainless steel, copper, aluminum, copper tungsten, the like, or combinations thereof. In another embodiment, the lid layer LL includes a ceramic material. In yet another embodiment, the lid layer LL includes a silicon containing material. In yet another embodiment, the lid layer LL includes a composite alloy. In yet another embodiment, the lid layer LL includes a plastic material. In some embodiments, the lid layer LL is a single contiguous material. In some other embodiment, the lid layer LL includes multiple pieces that may be the same or different materials. In some embodiments, the lid layer LL and the stiffener ring R have the same material. In some alternative embodiments, the lid layer LL and the stiffener ring R have different materials. In some embodiments, the material of the adhesive layer AD2 is similar to the material of the adhesive layer AD1. Therefore, the detailed description of the adhesive layer AD2 will be omitted herein.

In some embodiments, the TIM layer TL is located between the semiconductor dies 600 and the lid layer LL for heat dissipation. In some embodiments, the TIM layer TL is formed on the semiconductor dies 600 before attaching the lid layer LL on the stiffener ring R. In some embodiments, the material of the TIM layer TL includes Ag, Cu, Sn, In, carbon nanotube (CNT), graphite, or the like. In such case, the thermal conductivity (k) of the TIM layer TL is in a range of about 10 Wm⁻¹K⁻¹ to about 30 Wm⁻¹K⁻¹, such as about 10 Wm⁻¹K⁻¹. In some alternative embodiments, the material of the TIM layer TL includes a polymer material, solder paste, indium solder paste, or the like. In such alternative case, the thermal conductivity (k) of the TIM layer TL is in a range of about 0.1 Wm⁻¹K⁻¹ to about 10 Wm⁻¹K⁻¹, such as about 5 Wm⁻¹K⁻¹. In some embodiments, the semiconductor dies 600 may trap heat to become hot spots in the system package 1000. Therefore, the TIM layer TL thermally couples the semiconductor dies 600 and the lid layer LL to dissipate the heat from the semiconductor dies 600 to the lid layer LL.

In the present embodiment, as shown in FIG. 5, the lid layer LL and the stiffener ring R are independent elements connected by the adhesive layer AD2. However, the disclosure is not limited thereto. In some alternative embodiments, the lid layer LL and the stiffener ring R may be integrally formed as a lid with the same material. In such case, the lid is adhered on the substrate structure 10 by the adhesive layer AD1. Further, the TIM layer TL is located between the semiconductor dies 600 and the lid.

In accordance with an embodiment, a manufacturing method of a semiconductor package includes at least the following steps. A circuit substrate is provided, the circuit substrate comprises a first build-up layer on a first side of the circuit substrate, and a second build-up layer on a second side of the circuit substrate opposite to the first side. A first mask layer is formed with openings on the second build-up layer. A redistribution structure is formed over the second side while leaving the first side free of any redistribution structure, wherein forming the redistribution structure comprises forming first conductive vias through the openings of the first mask layer to be electrically connected with the second build-up layer. First conductive terminals are formed on the redistribution structure away from the first conductive vias. A singulation process is performed to cut through the redistribution structure, the mask layer and the circuit substrate to form a substrate structure.

In accordance with an embodiment, a manufacturing method of a semiconductor package includes at least the following steps. A circuit substrate is provided, the circuit substrate comprises a core layer, a first build-up layer on a first side of the core layer, and a second build-up layer on a second side of the core layer opposite to the first side. A mask layer is formed with openings on the second build-up layer. First conductive vias of a redistribution structure are formed on the mask layer and through the openings of the mask layer. A first dielectric layer of the redistribution structure is formed over the mask layer and laterally covers the first conductive vias.

In accordance with an embodiment, a manufacturing method of a semiconductor package includes at least the following steps. A circuit substrate is provided with a mask layer on a side of the circuit substrate. A redistribution structure having a first side and a second side opposite to the first side is formed, wherein forming the redistribution structure comprises forming first conductive vias at the first side through the mask layer to be electrically connected with the circuit substrate. Conductive terminals are formed on the second side of the redistribution structure. The redistribution structure, the mask layer underlying the redistribution structure and the circuit substrate underlying the mask layer are cut through to form a substrate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor package, comprising:
providing a circuit substrate, the circuit substrate comprising a first build-up layer on a first side of the circuit substrate, and a second build-up layer on a second side of the circuit substrate opposite to the first side;
forming a first mask layer with openings on the second build-up layer;
forming a redistribution structure over the second side while leaving the first side free of any redistribution structure, forming the redistribution structure comprising forming first conductive vias through the openings of the first mask layer to be electrically connected with the second build-up layer;
forming first conductive terminals on the redistribution structure away from the first conductive vias; and
performing a singulation process to cut through the redistribution structure, the mask layer and the circuit substrate to form a substrate structure.

2. The manufacturing method of claim 1, wherein forming the redistribution structure further comprises:
forming a first dielectric layer to laterally cover the first conductive vias;
forming N-th conductive vias over the first dielectric layer and the first conductive vias, wherein the N-th conductive vias are electrically coupled to the first conductive vias;
laterally covering the N-th conductive vias by an N-th dielectric layer stacked over the first dielectric layer; and
forming N-th conductive patterns over the N-th dielectric layer and the N-th conductive vias, wherein the N-th conductive patterns are electrically coupled to the first conductive vias through the N-th conductive vias.

3. The manufacturing method of claim 2, wherein the first conductive terminals are formed on the N-th conductive patterns to be in contact with the N-th conductive patterns.

4. The manufacturing method of claim 2, further comprising:
forming under-bump metallization (UBM) patterns on the N-th conductive patterns to be in contact with the N-th conductive patterns before forming the first conductive terminals.

5. The manufacturing method of claim 2, wherein a material of the N-th dielectric layer is different from a material of the first dielectric layer.

6. The manufacturing method of claim 1, further comprising:
forming a second mask layer with openings on the first build-up layer; and
forming second conductive terminals through the openings of the second mask layer to be electrically connected with the first build-up layer.

7. The manufacturing method of claim 6, wherein a critical dimension of the second conductive terminals is greater than a critical dimension of the first conductive terminals.

8. A manufacturing method of a semiconductor package, comprising:
providing a circuit substrate, the circuit substrate comprising a core layer, a first build-up layer on a first side of the core layer, and a second build-up layer on a second side of the core layer opposite to the first side;
forming a mask layer with openings on the second build-up layer;
forming first conductive vias of a redistribution structure on the mask layer and through the openings of the mask layer; and
forming a first dielectric layer of the redistribution structure over the mask layer and laterally covering the first conductive vias.

9. The manufacturing method of claim 8, wherein a top surface of the first dielectric layer is substantially leveled with a top surface of the first conductive vias.

10. The manufacturing method of claim 8, further comprising:
forming conductive terminals over an N-th dielectric layer of the redistribution structure and electrically coupled to the circuit substrate through the redistribution structure, the N-th dielectric layer being stacked over the first dielectric layer of the redistribution structure and away from the circuit substrate.

11. The manufacturing method of claim 10, wherein top surfaces of the conductive terminals each are substantially planar.

12. The manufacturing method of claim 10, wherein before forming the conductive terminals, further comprising:
forming under-bump metallization (UBM) patterns on N-th conductive patterns of the redistribution structure, the N-th conductive patterns being stacked over and electrically coupled to the first conductive vias of the redistribution structure and away from the circuit substrate, the N-th conductive patterns being disposed on the N-th dielectric layer, and the conductive terminals being disposed on the UBM patterns.

13. The manufacturing method of claim 10, further comprising:
performing a singulation process to cut through the redistribution structure, the mask layer and the circuit substrate to form a coterminous sidewall.

14. The manufacturing method of claim 13, further comprising:
mounting a semiconductor device over the N-th dielectric layer of the redistribution structure and electrically coupled to the redistribution structure through the conductive terminals.

15. A manufacturing method of a semiconductor package, comprising:
providing a circuit substrate with a mask layer on a side of the circuit substrate;
forming a redistribution structure having a first side and a second side opposite to the first side, forming the redistribution structure comprising forming first conductive vias at the first side through the mask layer to be electrically connected with the circuit substrate;
forming conductive terminals on the second side of the redistribution structure; and
cutting through the redistribution structure, the mask layer underlying the redistribution structure and the circuit substrate underlying the mask layer to form a substrate structure.

16. The manufacturing method of claim 15, wherein the circuit substrate is provided with circuit regions separated by scribe line regions, redistribution layers of the redistribution structure are formed within the circuit regions, and the redistribution structure, the mask layer and the circuit substrate are cut through along the scribe line regions.

17. The manufacturing method of claim 15, wherein forming the redistribution structure further comprises:
forming a first dielectric layer to laterally cover the first conductive vias;
forming N-th conductive vias over the first dielectric layer and the first conductive vias, wherein the N-th conductive vias are electrically coupled to the first conductive vias;
laterally covering the N-th conductive vias by an N-th dielectric layer stacked over the first dielectric layer; and
forming N-th conductive patterns over the N-th dielectric layer and the N-th conductive vias, wherein the N-th conductive patterns are electrically coupled to the first conductive vias through the N-th conductive vias.

18. The manufacturing method of claim 17, further comprising:
forming under-bump metallization (UBM) patterns on the N-th conductive patterns to be in contact with the N-th conductive patterns before forming the conductive terminals.

19. The manufacturing method of claim 17, wherein forming the redistribution structure further comprises:
mounting a die beside the N-th conductive vias, wherein the die is covered by the N-th dielectric layer and electrically coupled to the N-th conductive patterns.

20. The manufacturing method of claim 15, further comprising:
mounting a semiconductor device over the substrate structure through the conductive terminals.
